(19) United States
(12) Patent Application Publication
(10) Pub. No.: US 2022/0204338 A1
(43) Pub. Date: Jun. 30, 2022

(54) BACKSIDE COATING OF SUSPENDED MEMS MIRROR ACTUATORS FOR STRESS MATCHING AND THERMAL STABILITY

(71) Applicant: Beijing Voyager Technology Co., Ltd., Beijing (CN)

(72) Inventors: Sae Won Lee, Mountain View, CA (US); Youmin Wang, Mountain View, CA (US)

(21) Appl. No.: 17/135,854

(22) Filed: Dec. 28, 2020

(51) Int. Cl. B81B 3/00; B81C 1/00; G02B 26/08; G02B 1/11; G02B 26/10; G02B 7/18; G01S 7/481

(52) U.S. Cl. CPC B81B 3/0072; B81C 1/00666; G02B 26/0833; G02B 1/11; B81C 2203/036; G02B 7/181; G01S 7/4817; B81B 2201/042; B81C 2201/0132; G02B 26/101

(57) ABSTRACT

Apparatus and methods for forming MEMS structures that minimize bending with temperature change due to differences in the coefficient of thermal expansion for different layers of the MEMS structures. In particular, shown is forming a compensating reflectivity coating on the underside of a suspended MEMS structure to offset bending by a reflectivity coating on a top side of the suspended MEMS structure. The reflectivity coating can be either a reflective coating, or a non-reflective (anti-reflective) coating. The method includes forming a cavity on a first wafer, forming the compensating reflective coating on a second wafer substrate that will become the suspended MEMS structure, then flipping the second wafer over and bonding the two wafers together.

### BACKGROUND OF THE INVENTION

Unless otherwise indicated herein, the materials described in this section are not prior art to the claims in this application and are not admitted to be prior art by inclusion in this section. In particular, disparate technologies are discussed that it would not be obvious to discuss together absent the teachings of the present invention.

Modern vehicles are often equipped with sensors designed to detect objects and landscape features around the vehicle in real-time to enable technologies such as lane change assistance, collision avoidance, and autonomous driving. Some commonly used sensors include image sensors (e.g., infrared or visible light cameras), acoustic sensors (e.g., ultrasonic parking sensors), radio detection and ranging (RADAR) sensors, magnetometers (e.g., passive sensing of large ferrous objects, such as trucks, cars, or rail cars), and light detection and ranging (LiDAR) sensors.

A LiDAR system typically uses a light source and a light detection system to estimate distances to environmental features (e.g., pedestrians, vehicles, structures, plants, etc.). For example, a LiDAR system may transmit a light beam (e.g., a pulsed laser beam) to illuminate a target and then measure the time it takes for the transmitted light beam to arrive at the target and then return to a receiver near the transmitter or at a known location. In some LiDAR systems, the light beam emitted by the light source may be steered across a two-dimensional or three-dimensional region of interest according to a scanning pattern, to generate a “point cloud” that includes a collection of data points corresponding to target points in the region of interest. The data points in the point cloud may be dynamically and continuously updated, and may be used to estimate, for example, a distance, dimension, location, and speed of an object relative to the LiDAR system.

Light steering typically involves the projection of light in a pre-determined direction to facilitate, for example, the detection and ranging of an object, the illumination and scanning of an object, or the like. Light steering can be used in many different fields of applications including, for example, autonomous vehicles, medical diagnostic devices, etc., and can be configured to perform both transmission and reception of light. For example, a light steering transmitter may include a micro-mirror to control the projection direction of light to detect/image an object. Moreover, a light steering receiver may also include a micro-mirror to select a direction of incident light to be detected by the receiver, to avoid detecting other unwanted signals. A micro-mirror assembly typically includes a micro-mirror and an actuator. In a micro-mirror assembly, a mirror-mirror can be connected to a substrate via a connection structure (e.g., a torsion bar, a spring, etc.) to form a pivot point. One such type of micro-mirror assembly can be a micro-electro-mechanical system (MEMS)-type structure that may be used for a light detection and ranging (LiDAR) system in an autonomous vehicle, which can be configured for detecting objections and determining their corresponding distances from the vehicle. LiDAR systems typically work by illuminating a target with an optical pulse and measuring the characteristics of the reflected return signal. The return signal is typically captured as a point cloud. The width of the optical-pulse often ranges from a few nanoseconds to several microseconds.

MEMS micro-mirrors are considered as a good alternative to reduce the cost of LIDAR systems. In order to have enough resolution for long range detection for LIDAR applications, it is imperative that MEMS micro-mirrors achieve small divergence under various operating conditions. If a micro-mirror is used in a LIDAR system and its divergence is sensitive to temperature variations, long range and even mid-range scanning ability would be lost outside a very narrow temperature range. When creating reflective micro-mirrors using standard MEMS processes, properties of the resulting structure to be considered are reflectivity, residual film stress, and modulus of elasticity, to name a few. To achieve desired values for these parameters, it may require that multiple layers with different material properties be used together. Reflective film as well as anti-reflective film would need to be used to maximize steering of the light beam while minimizing the intensity of a static light spot. The rotating MEMS mirror is made of a reflective material, while stationary support structures are coated with an anti-reflective coating, to avoid light noise at other than the desired mirror angle. Both metals (typically used to make MEMS structures reflective and/or electrically conductive) and dielectric materials (which are typically used for anti-reflective layers) have quite different coefficients of thermal expansions (CTEs) compared to semiconductor materials typically used for MEMS structures. This results in bi-morph stresses and surface bow even with slight temperature variations.

### BRIEF SUMMARY OF THE INVENTION

Techniques disclosed herein relate generally to apparatus and methods for forming MEMS structures that minimize bending with temperature change due to differences in the coefficient of thermal expansion for different layers of the MEMS structures. More specifically, and without limitation, disclosed herein are methods and apparatus for forming a compensating reflectivity coating on the underside of a suspended MEMS structure to offset bending by a reflectivity coating on a top side of the suspended MEMS structure.

In certain embodiments, the reflectivity coating can be either a reflective coating, or a non-reflective (anti-reflective) coating. The method includes forming a cavity on a first wafer, forming the compensating reflective coating on a second wafer substrate that will become the suspended MEMS structure, then flipping the second wafer over and bonding the two wafers together. Normally, wafer bonding is done through an oxide layer. However, to support an electrical connection through the bonded area, the oxide insulator is removed.

In certain embodiments, a method is provided for forming a compensating reflectivity layer on an underside of suspended structures. A cavity region is formed on a first wafer substrate. On a second wafer, a silicon layer is formed over the second wafer substrate. A compensating reflectivity coating is deposited on the silicon layer. The compensating reflectivity coating is etched with a pattern to leave a backside compensating reflectivity coating. The second wafer substrate is flipped over, and first areas without the compensating reflectivity coating are aligned with second areas without the cavity region on the first wafer substrate. The first and second areas are bonded to each other, then the second wafer substrate (a handling layer) is removed. The front side reflective and anti-reflective coatings are formed over the silicon layer, such that one of the reflective and anti-reflective coatings are opposite the backside compensating reflectivity coating to compensate for bending due to temperature changes and differences in coefficients of thermal expansion. Finally, the anti-reflective coating and silicon layer are etched to form a micro structure.

In certain embodiments, the cavity is a mirror cavity and the micro structure is a micro-electromechanical system (MEMS) micro mirror structure. The compensating reflectivity coating is a dielectric anti-reflective coating. No compensation is provided for the reflective coating (mirror) where the reflective coating can be made thin enough to avoid any significant bending with temperature. The micro mirror structure includes anchors and comb fingers with anti-reflective coatings, and thus a dielectric anti-reflective coating is formed on the backside of the comb fingers and suspended portions of the anchors.

In some embodiments, the step of aligning areas for bonding the two wafers comprises aligning protrusions at edges of the cavity region with recesses formed at areas between the compensating reflectivity coating. Once aligned, the two wafers are bonded with a high temperature anneal.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, it should be understood that, although the present system and methods have been specifically disclosed by examples and optional features, modification and variation of the concepts herein disclosed should be recognized by those skilled in the art, and that such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following specification, claims, and accompanying drawings.

### BRIEF DESCRIPTION OF THE DRAWINGS

The features of the various embodiments described above, as well as other features and advantages of certain embodiments of the present invention, will be more apparent from the following detailed description taken in conjunction with the accompanying drawings, in which:

FIG. 1 shows an autonomous vehicle with a LiDAR system, according to certain embodiments;

FIG. 2A shows an example of a light projection operation, according to certain embodiments;

FIG. 2B shows an example of a light detection operation, according to certain embodiments;

FIG. 3 is a diagram of the structure of a typical prior art MEMS mirror;

FIG. 4 is a sectional view of FIG. 3 along lines A-A, illustrating the reflective and non-reflective coatings;

FIG. 5 is a diagram illustrating non-reflective coatings, and optional reflective coatings, on the underside of the suspended structures of a MEMS mirror, according to certain embodiments;

FIGS. 6A-T are diagrams illustrating the structures formed in a process for creating a non-reflective backside coating, according to certain embodiments;

FIG. 7 is a flow chart of a method for creating a non-reflective backside coating, according to certain embodiments;

FIG. 8 illustrates a simplified block diagram showing aspects of a LiDAR-based detection system, according to certain embodiments of the invention; and

FIG. 9 illustrates an example computer system that may be utilized to implement techniques disclosed herein, according to certain embodiments of the invention.

### DETAILED DESCRIPTION OF THE INVENTION

Aspects of the present disclosure relate generally to compensating for bending due to differences in the coefficient of thermal expansion between layers of a MEMS structure, and more particularly to LiDAR systems, according to certain embodiments.

In the following description, various examples of a compensation method and apparatus are described. For purposes of explanation, specific configurations and details are set forth in order to provide a thorough understanding of the embodiments. However, it will be apparent to one skilled in the art that certain embodiments may be practiced or implemented without every detail disclosed. Furthermore, well-known features may be omitted or simplified in order to prevent any obfuscation of the novel features described herein.

The following high level summary is intended to provide a basic understanding of some of the novel innovations depicted in the figures and presented in the corresponding descriptions provided below. Aspects of the invention relate to forming a compensating reflectivity coating on the underside of a suspended MEMS structure to offset bending by a reflectivity coating on a top side of the suspended MEMS structure.

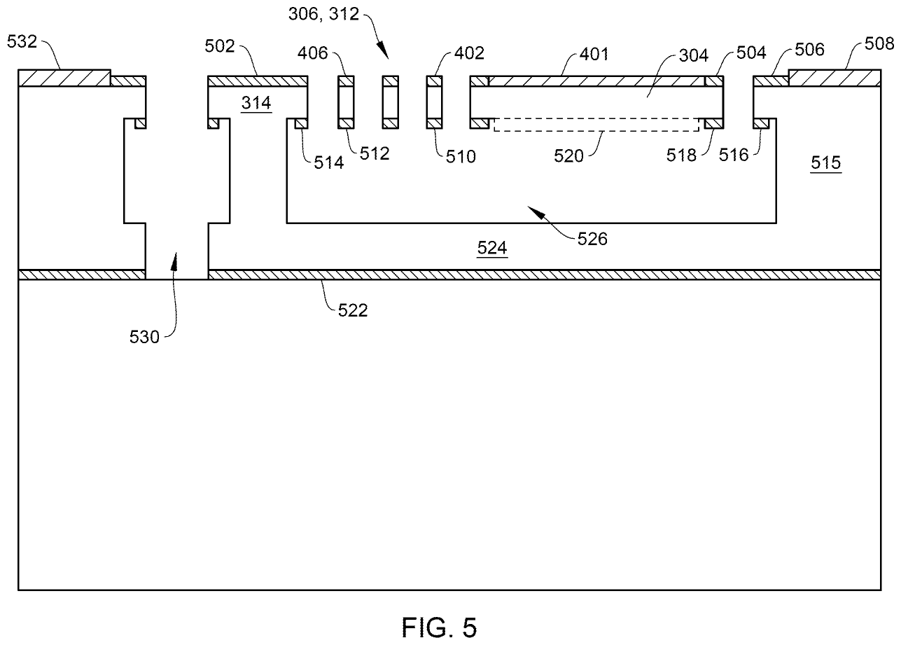

As discussed in further detail below, a micro-electromechanical system (MEMS) structure with a cavity region 526 on a first wafer substrate 524 is shown in FIG. 5. A suspended silicon layer 304 is over the cavity region. A front side reflective coating 401 is over the suspended silicon layer. A front side anti-reflective coating (402, 406, 502, 504, 506) is over the suspended silicon layer. A backside compensating reflectivity coating (510, 512, 514, 518, 520) is on a bottom surface of the suspended silicon layer, inside the cavity, positioned opposite of either the front side reflective coating or the front side anti-reflective coating. The backside compensating reflectivity coating compensates for bending due to temperature change induced bending due to differences in coefficients of thermal expansion.

Embodiments describe a flat, electrostatically actuated micro-mirror or micro-mirror array that is used to scan a wide field of view with a single or multiple light sources with minimum divergence by utilizing stress matching layer(s) for both reflective and/or anti-reflective layer(s). In order to improve the optical gain, the size of the mirror or mirror array is maximized without sacrificing optical surface flatness for long range resolution. The main structural layer(s) would typically start with a minimal stress gradient throughout the thickness. One or more materials can be used to provide reflective and anti-reflective properties on different parts of the MEMS device surface to maximize scanned light efficiency while minimizing reflected static light which is not beneficial for light detection and may be of concern for eye safety.

Embodiments describe the use of materials with the same or similar physical properties as the materials used for the mirror's or mirror array's reflective and anti-reflective layer(s) on the other side of the device structures, in order to cancel out the bi-morph film stress and also provide thermal stability over a wide range of temperature. This applies to both the reflective mirror structure(s) as well as non-mirror structures such as torsion beams, hinges and springs to name a few. The main purpose of the structural layer is to create a base for the flat micro-mirror surface while providing target mechanical properties such as a large deflection angle from the micro-mirror hinges, minimal dynamic deformation on the reflective surface and high enough resonant frequency to achieve a target operating frequency. Usage of this matching layer(s) can be applied to devices that are made with either a single wafer or multiple wafers processed with wafer bonding.

In embodiments where micro-mirror MEMS devices are made using a single wafer, typically a SOI (silicon-on-insulator) wafer is used with a device layer used to define mirror structures and a handling layer used to create cavities to provide space for the mirrors to move. In this method of building micro-mirrors, the cavity is first removed from the handling layer before stress matching reflective and anti-reflective layers can be deposited and patterned. However, due to the recess created by the cavity within the handling layer, patterning of the layer(s) can be challenging. One may choose to deposit but not pattern material(s) to minimize stress mismatch to achieve fabrication simplicity.

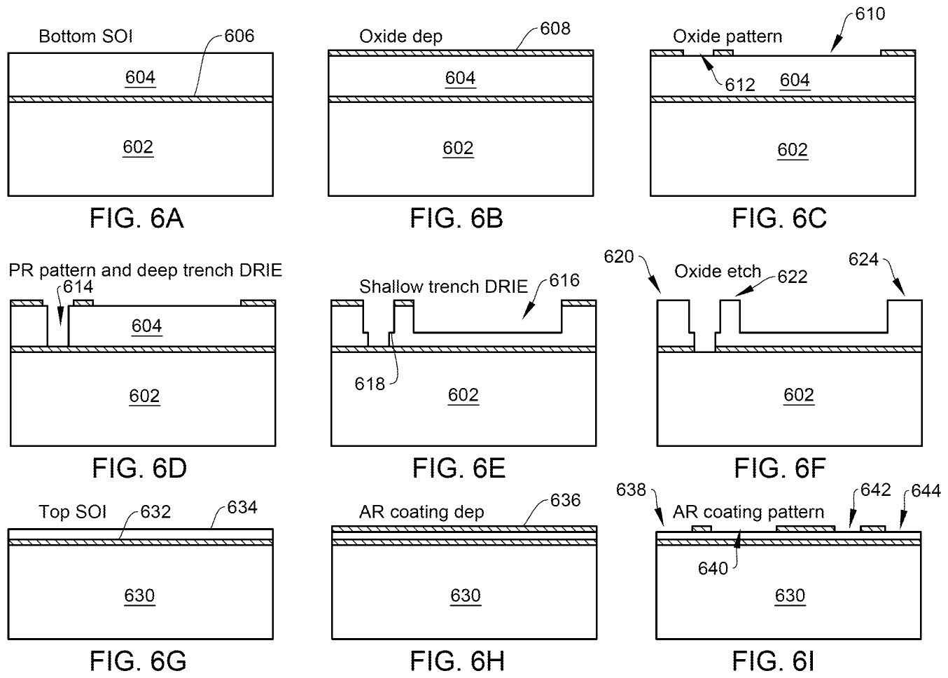

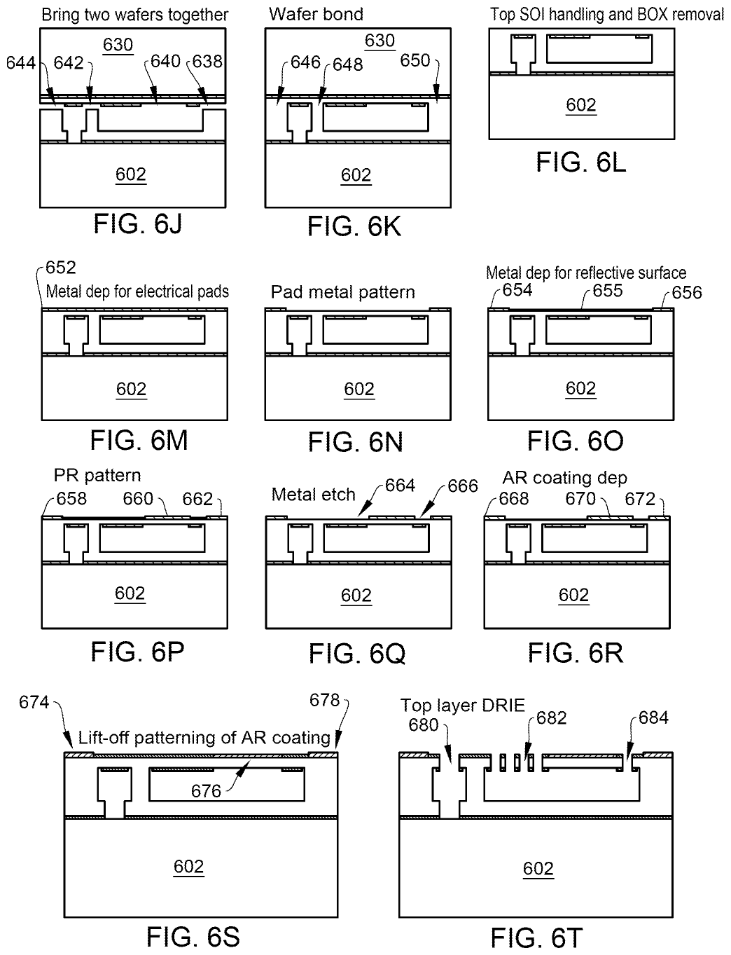

In a two wafer embodiment, the method includes forming a cavity on a first wafer, forming the compensating reflective coating on a second wafer substrate that will become the suspended MEMS structure, then flipping the second wafer over and bonding the two wafers together. In this case where multiple wafers are bonded to create micro-mirror MEMS devices, the patterning of stress matching layer(s) is more straightforward. For illustration purposes, micro-mirror devices can be made with two SOI wafers with a wafer bonding process. The device layer of one of the SOI wafers is used to create cavities for micro-mirrors to move. The device layer of the other SOI wafer is used for creating micro-mirror structures (See FIG. 6F, described below). The handling layer of the SOI wafer, used to build the micro-mirror structures, is removed along with the BOX (buried oxide) layer to keep only the device layer (See FIG. 6I). This is similar to transferring a thin Si layer with well-defined thickness for making MEMS structures. Reflective layer(s) and anti-reflective layer(s) can be added after that on top of the bonded device layer. After the wafer bonding, the backside of the micro-mirror structures cannot be accessed. Thus, stress matching layer(s) are deposited and patterned before the wafer bonding.

With the two SOI wafer process, patterning of the reflective and anti-reflective layers is simpler and follows typical photolithography and etching processes used in MEMS fabrication. Typical wafer bonding processes for making micro-mirror MEMS devices involve Si—Si wafer bonding to provide electrical connections not only through the top structural layer, but also through the cavity layer. Thus, anti-reflective dielectric layers are patterned away from areas where wafer bonding occurs (FIG. 6I). The mating surfaces of both wafers already has patterned features and the wafers are aligned during the wafer bonding process. Both SOI wafers have alignment marks already patterned and aligned before the actual bonding occurs. One consideration during a typical Si etching process is to not expose a metal layer such as Au during the etching process, to prevent contamination of the etch tool. The top Si micro-mirror structural layer etch happens after the wafer bonding in the discussed process flow, and there is no metal on the backside of the area where Si etch happens (FIG. 6T).

This dual wafer process is described in detail below. First, a description of an overall LiDAR system into which the embodiments are placed will provide context.

### Typical Lidar System Environment for Certain Embodiments of the Invention

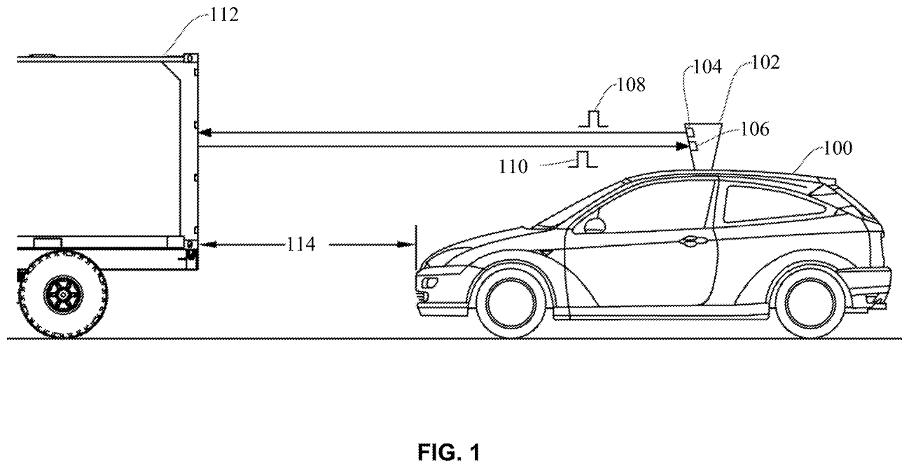

FIG. 1 illustrates an autonomous vehicle 100 in which the various embodiments described herein can be implemented. Autonomous vehicle 100 can include a LiDAR module 102. LiDAR module 102 allows autonomous vehicle 100 to perform object detection and ranging in a surrounding environment. Based on the result of object detection and ranging, autonomous vehicle 100 can drive according to the rules of the road and maneuver to avoid a collision with detected objects. LiDAR module 102 can include a light steering transmitter 104 and a receiver 106. Light steering transmitter 104 can project one or more light signals 108 at various directions (e.g., incident angles) at different times in any suitable scanning pattern, while receiver 106 can monitor for a light signal 110 which is generated by the reflection of light signal 108 by an object. Light signals 108 and 110 may include, for example, a light pulse, a frequency modulated continuous wave (FMCW) signal, an amplitude modulated continuous wave (AMCW) signal, etc. LiDAR module 102 can detect the object based on the reception of light signal 110, and can perform a ranging determination (e.g., a distance of the object) based on a time difference between light signals 108 and 110, as would be appreciated by one of ordinary skill in the art with the benefit of this disclosure. For example, as shown in FIG. 1, LiDAR module 102 can transmit light signal 108 at a direction directly in front of autonomous vehicle 100 at time T1 and receive light signal 110 reflected by an object 112 (e.g., another vehicle) at time T2. Based on the reception of light signal 110, LiDAR module 102 can determine that object 112 is directly in front of autonomous vehicle 100. Moreover, based on the time difference between T1 and T2, LiDAR module 102 can also determine a distance 114 between autonomous vehicle 100 and object 112. Autonomous vehicle 100 can thereby adjust its speed (e.g., slowing or stopping) to avoid collision with object 112 based on the detection and ranging of object 112 by LiDAR module 102.

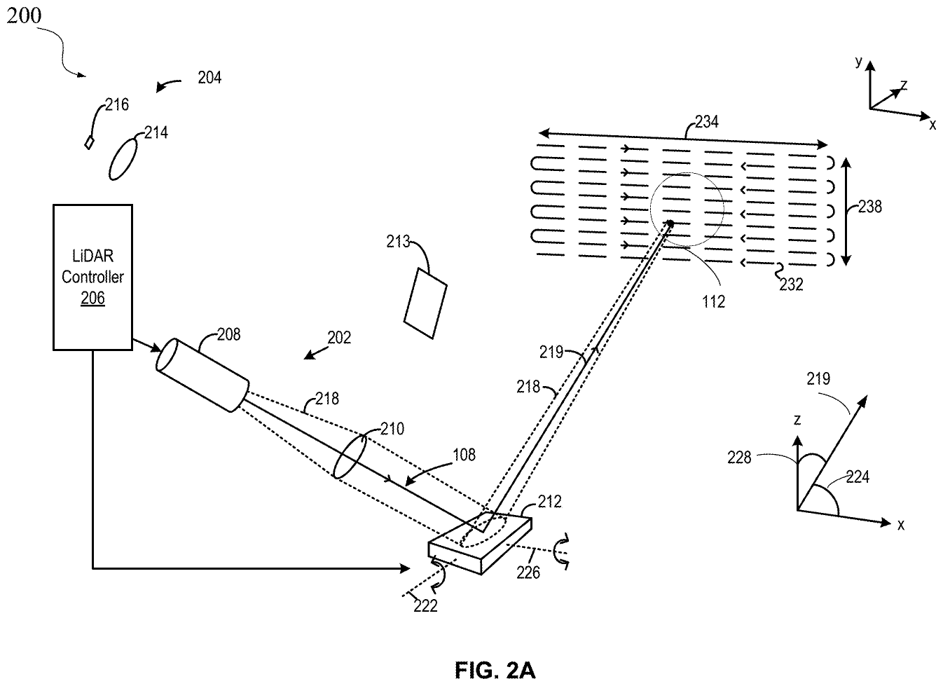

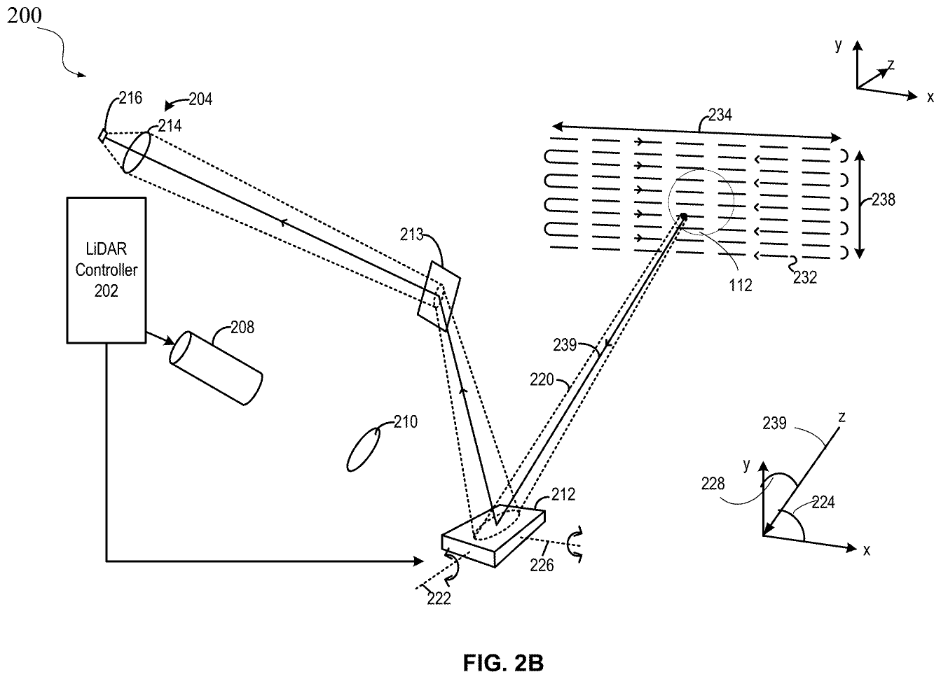

FIG. 2A and FIG. 2B illustrate simplified block diagrams of an example of a LiDAR module 200 according to certain embodiments. LiDAR module 200 may be an example of LiDAR system 102, and may include a transmitter 202, a receiver 204, and LiDAR controller 206, which may be configured to control the operations of transmitter 202 and receiver 204. Transmitter 202 may include a light source 208 and a collimator lens 210, and receiver 204 can include a lens 214 and a photodetector 216. LiDAR module 200 may further include a mirror assembly 212 (also referred to as a “mirror structure”) and a beam splitter 213. In some embodiments, LiDAR module 102, transmitter 202 and receiver 204 can be configured as a coaxial system to share mirror assembly 212 to perform light steering operations, with beam splitter 213 configured to reflect incident light reflected by mirror assembly 212 to receiver 204.

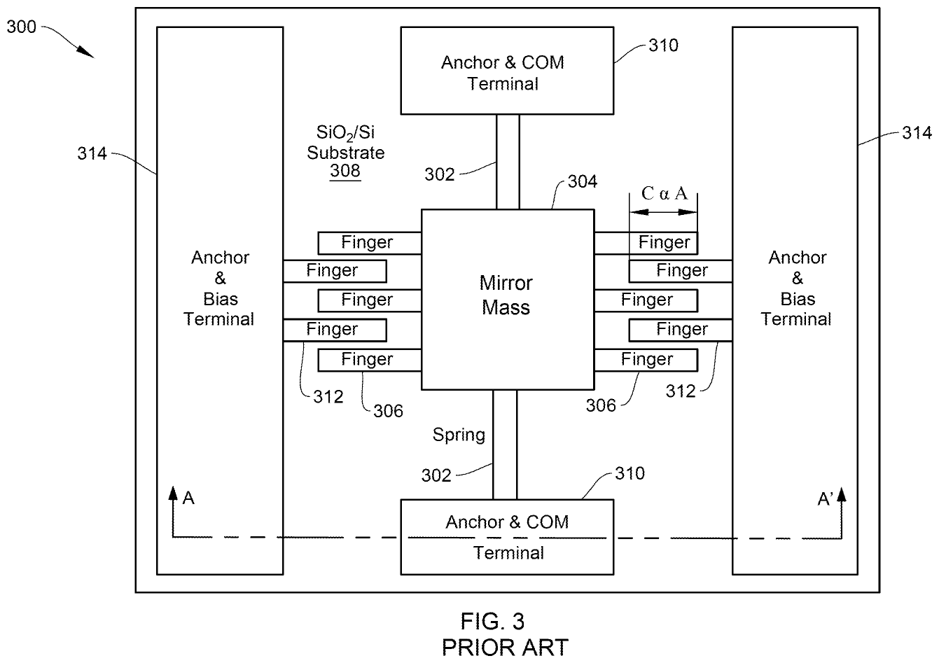

FIG. 2A shows an example of a light projection operation, according to certain embodiments. To project light, LiDAR controller 206 can control light source 208 (e.g., a pulsed laser diode, a source of FMCW signal, AMCW signal, etc.) to transmit light signal 108 as part of light beam 218. Light beam 218 can disperse upon leaving light source 208 and can be converted into collimated light beam 218 by collimator lens 210. Collimated light beam 218 can be incident upon a mirror assembly 212, which can reflect collimated light beam 218 to steer it along an output projection path 219 towards object 112. Mirror assembly 212 can include one or more rotatable mirrors. FIG. 2A illustrates mirror assembly 212 as having one mirror; however, a micro-mirror array may include multiple micro-mirror assemblies that can collectively provide the steering capability described herein. Mirror assembly 212 can further include one or more actuators (not shown in FIG. 2A) to rotate the rotatable mirrors. The actuators can rotate the rotatable mirrors around a first axis 222, and can rotate the rotatable mirrors along a second axis 226. The rotation around first axis 222 can change a first angle 224 of output projection path 219 with respect to a first dimension (e.g., the x-axis), whereas the rotation around second axis 226 can change a second angle 228 of output projection path 219 with respect to a second dimension (e.g., the z-axis). LiDAR controller 206 can control the actuators to produce different combinations of angles of rotation around first axis 222 and second axis 226 such that the movement of output projection path 219 can follow a scanning pattern 232. A range 234 of movement of output projection path 219 along the x-axis, as well as a range 238 of movement of output projection path 219 along the z-axis, can define a FOV. An object within the FOV, such as object 112, can receive and reflect collimated light beam 218 to form reflected light signal, which can be received by receiver 204 and detected by the LiDAR module, as further described below with respect to FIG. 2B. In certain embodiments, mirror assembly 212 can include one or more comb spines with comb electrodes (see, e.g., FIG. 3), as will be described in further detail below.

FIG. 2B shows an example of a light detection operation, according to certain embodiments. LiDAR controller 206 can select an incident light direction 239 for detection of incident light by receiver 204. The selection can be based on setting the angles of rotation of the rotatable mirrors of mirror assembly 212, such that only light beam 220 propagating along light direction 239 gets reflected to beam splitter 213, which can then divert light beam 220 to photodetector 216 via collimator lens 214. With such arrangements, receiver 204 can selectively receive signals that are relevant for the ranging/imaging of object 112 (or any other object within the FOV), such as light signal 110 generated by the reflection of collimated light beam 218 by object 112, and not to receive other signals. As a result, the effect of environmental disturbance on the ranging and imaging of the object can be reduced, and the system performance may be improved.

### Micro Mirror Structure

FIG. 3 is a diagram of the structure of a prior art MEMS mirror with both reflective and non-reflective (sometimes referred to an anti-reflective) surfaces. FIG. 3 is not to scale, typically the non-reflective area is about 20% of the total area, while the reflective area is around 80%. The non-reflective areas have been shown as larger, and with bigger gaps, for ease of understanding. FIG. 3 shows a typical electrostatic MEMS mirror structure 300 with springs 302, a mirror mass 304, and comb fingers 306, 312. The mirror mass 304 is coated with a reflective coating (e.g., a metal), while the springs and comb fingers are coated with a non-reflective coating (e.g., a dielectric). The mirror mass 304 is suspended by mechanical springs 302 which are typically anchored in a SiO₂/silicon substrate 308 and anchored at anchor and COM (sometimes referred to as simply “common” or “COM”) terminals 310. COM terminals 310 are also non-reflective. Comb fingers 306 are connected to mirror mass 304, and are interleaved with comb fingers 312 connected to anchor and bias (sometimes referred to as simply “bias”) terminals 314. Terminals 310 provide for a common (COM) connection with the mirror, both providing a driving voltage and sensing a change in capacitance between the fingers 306 connected to mirror mass 304, and interleaved fingers 312 connected to anchor and bias terminals 314. Anchor and bias terminals 314 are connected to a voltage bias, which is typically an AC voltage. Anchor and bias terminals 314 are also non-reflective.

As shown, this structure allows rotation around the axis of the springs 302. In another embodiment not shown in order to not complicate the diagram, additional springs can be provided to give a second, orthogonal axis of rotation of the mirror mass 304. Additional interleaved comb fingers are then provided, connected to separate bias and COM anchor terminals. Again, the additional comb fingers and bias and COM terminals would be non-reflective.

As described above, FIG. 3 is not to scale, and is just an example of a MEMS mirror structure. A bigger area overlap (larger fingers and smaller gap between them) gives bigger capacitance and actuation force but it also reduces the quality factor due to the air friction between them (damping). The fingers gap is also limited by fabrication; an achievable aspect ratio (device thickness over feature size) is around 20. Higher capacitance is easier to measure and provides larger forces but it is limited by fabrication and reduces the quality factor. Other designs do not use the comb fingers, but instead a larger mirror area with activation electrodes in the bottom of the cavity to attract one side of the mirror by electrostatic force and thus provide the desired tilt.

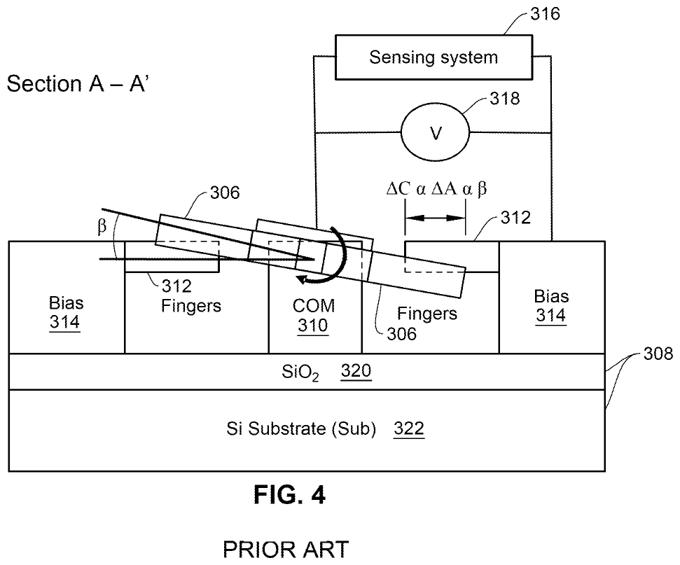

FIG. 4 is a sectional view of FIG. 3 along lines A-A. As can be seen from FIG. 4, mirror mass 304 tilts when a driving voltage 318 (V) is applied across the comb fingers 306, 312, between COM terminal 310 and bias terminal 314. Since the overlap area in the fingers changes along with the mirror mass displacement, the capacitance of the comb fingers changes proportionally and it is sensed by sensing system 316 and used as feedback to control the motion of the mirror mass. As shown, the overlap between the fingers 306 and 312 changes, with a change in capacitance (AC) that is proportional to the change in overlap area (AA), which is proportional to the tilt angle (3.

FIG. 4 shows a reflective, metal coating 401 over the mirror mass 304. Non-reflective coatings 402 and 404 are formed over the mirror comb fingers 306, and non-reflective coatings 406 and 408 are formed over the bias fingers 312. The mirror reflective metal material can be, for example, gold, silver, rhodium, platinum, copper or aluminum. The reflective metal films typically have a thickness of about 20 nm to about 2000 nm. The metal film is connected to ground through anchors. The mirror body is typically a silicon substrate. A bond layer can be added between the reflective metal film and the substrate in order to adhere the reflective metal film to the silicon substrate. Both metals, typically used to make MEMS structures reflective and/or electrically conductive, and dielectric materials, which are typically used for non-reflective layer(s), have quite different coefficients of thermal expansions (CTEs) compared to semiconductor materials typically used for MEMS structures. Thus, for suspended structures, such as the mirror and the comb fingers, this results in bi-morph stresses and surface bow even with slight temperature variation.

### Backside Coating

FIG. 5 is a cut-away diagram illustrating non-reflective coatings, and optional reflective coatings, on the underside of the suspended structures of a MEMS mirror, according to certain embodiments. FIG. 5 is illustrative, and is not to scale and is not a pure cut-away view. It shows mirror mass 304 with reflective metal coating 401 on top. It also shows comb fingers 306, 312. On top of the comb fingers are non-reflective coatings 402, 406. The anchors also have non-reflective coatings, such as non-reflective coating 502 on ground bias anchor 314, and non-reflective coating 506. Additionally, a metal contact 508 is shown on structure 515, and is typically thicker than the metallic, reflective mirror coating 401.

In embodiments, backside non-reflective coatings are added, such as backside non-reflective coatings 510 and 512 beneath the comb fingers, backside non-reflective coating 514 beneath a suspended lip of anchor 314 and backside non-reflective coating 516. With changes in temperature, the topside coatings would normally cause the suspended structures to bow or bend. But the backside non-reflective coatings bend as well with temperature, but since they are on the backside cause a bend in the opposite direction. Thus, the bending substantially cancels out. Portions of the structures that are not suspended, and instead are supported to substrate 524, do not have the same bending issues since the thickness of the substrate avoids any significant bending. For example, anchor 314 extends all the way down to below the cavity 526 of the MEMS mirror structure.

In embodiments, an optional reflective backside coating 520 is added to cancel out bending caused by a mismatch between mirror reflective coating 401 and silicon mirror mass 304. However, in many designs mirror reflective coating 401 (unlike the non-reflective dielectric) can be made sufficiently thin so that no significant bending occurs, and thus reflective backside coating 520 is not necessary and can be omitted. For example, the mirror reflective coating 401 can be as thin as 75 nm.

In embodiments, an electrical connection to terminal 314 is formed through layer 24 beneath the cavity, to structure 515, which is connected to electrical contact 508. By etching cavity 530 through to oxide layer 522, this electrical connection is isolated from other electrical contacts, such as electrical contact 532.

FIGS. 6A-T are diagrams illustrating the structures formed in a process for creating a non-reflective backside coating, according to certain embodiments. In FIG. 6A, a substrate 602 is shown, with a buried oxide (BOX) layer 606 and further silicon layer 604. In FIG. 6B, an oxide layer 608 is added.

FIG. 6C shows the etching away of portions 612 and 610 of oxide layer 608, using an oxide etch mask. FIG. 6D shows a PR (Photo Resist) pattern being applied, and a deep trench 614 being created using photoresist instead of an oxide etch mask. A Deep Reactive Iron Etch (DRIE) is done, which involves covering the sidewall with a polymer as etching proceeds, so that the etch doesn't widen the hole. By covering the sidewalls of the trench with a polymer, etching can be done just in the vertical direction. This is performed repeatedly, etching and passivating (covering walls with polymer), until the desired depth is reached.

FIG. 6E shows a shallow trench 616 being etched, which at the same time widens the upper part of trench 614 to create shoulder 618. As described below, trench 614 will become the mirror cavity, and trench 614 provides for isolating an electrical connection through the bottom of the cavity. In FIG. 6F, the remaining oxide 608 is etched away at positions 620, 622 and 624 in an oxide etch.

FIG. 6G illustrates the preparation of the backside layer using a separate wafer. The new, second wafer has a substrate 630 with an oxide layer 632 and a thin silicon layer 634. This provides a Silicon on Insulator (SOI) structure. Layer 634 will later become the suspended portions of the mirror structure, after flipping the wafer. In FIG. 6H, an AR (Anti-Reflective) coating 636 is deposited. This can be a dielectric, such as silicon dioxide, aluminum oxide and titanium oxide. The thickness of the AR coating is determined by the refractive index of AR coating and the laser wavelength used. FIG. 6I shows the backside anti-reflective coating pattern formed by etching away the dielectric anti-reflective coating 636 at positions 638, 640, 642 and 644.

FIG. 6J shows the second wafer of FIGS. 6G-I, with substrate 620, flipped upside down and positioned over the first wafer with substrate 602. The etched away portions of the dielectric anti-reflective coating from FIG. 6I at positions 638, 640, 642 and 644, form recesses to engage the protruding elements of the first wafer adjacent the cavities and allow alignment of the structures. The two wafers are then bonded together to form the structure of FIG. 6K, with bonding at positions 646, 648 and 650. The bonding is done with a high temperature anneal. By aligning over the features as shown, this avoids having the anti-reflective coating over the bonding areas, insuring both alignment and a solid bond. Substrate 630 functions as a handling layer during the bonding process.

FIG. 6L shows the handling layer, substrate 630, removed. This is done with a first, coarse step, and a second, fine step. First, mechanical grinding is used to remove most of this top handling substrate layer 630. Next, a silicon etcher (with an oxide pattern) is used for finer accuracy after the mechanical grinder reaches near the end of substrate 630. Finally, the BOX (buried oxide) layer 632 is removed.

FIG. 6M illustrates the deposition of a metal contact layer 652 for electrical pads. The portion not used is etched away to provide the structure shown in FIG. 6N. Next, metal deposition layer 655 is added for the mirror reflective surface. This layer is thinner than areas 654 and 656, which form the electrical pads for wire bonding connections.

FIG. 6P illustrates the application of a photo resist pattern to eliminate metal layer 655 in areas where the mirror reflective coating is not desired. Where the mirror coating is to remain, the photoresist stays. These are the mirror area photoresist 660, and photoresist 658 and 662 over the electrical pad areas. The electrical pads are made a bit thicker by having the extra metal layer applied, giving the desired thicker pads. A metal etch is then performed to leave open areas 664 and 666 as shown in FIG. 6Q.

FIG. 6R illustrates the anti-reflective coating being added, including areas 668, 670 and 672 over the electrical pads and the mirror. The anti-reflective coating in between these areas is the part that is desired. These areas still have the same photoresist from the previous step (saving a process step), allowing the subsequent removal of the anti-reflective coating where it isn't desired. These portions on photoresist (over the mirror and electrical pads) are removed by removing the photo resist, which also removes the antireflective layer over the photoresist. This leaves the structure shown in FIG. 6S, with the photoresist and anti-reflective layers removed from areas 674, 676 and 678. In one embodiment, lithography can be used.

FIG. 6T illustrates the final product after etching steps to form the comb fingers and other structures by etching away areas 680, 682, 684 etc.

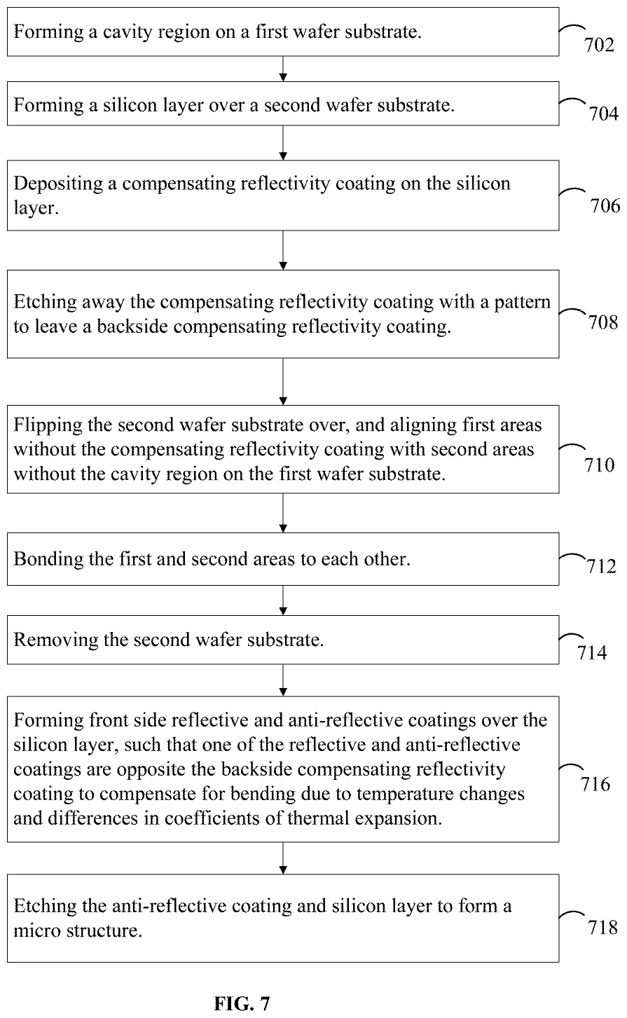

FIG. 7 is a flow chart of a method for forming a compensating reflectivity layer on an underside of suspended structures. Step 702 is forming a cavity region on a first wafer substrate. Step 704 is forming a silicon layer over a second wafer substrate. Step 706 is depositing a compensating reflectivity coating on the silicon layer. Step 708 is etching away the compensating reflectivity coating with a pattern to leave a backside compensating reflectivity coating. Step 710 is flipping the second wafer substrate over, and aligning first areas without the compensating reflectivity coating with second areas without the cavity region on the first wafer substrate. Step 712 is bonding the first and second areas to each other. Step 714 is removing the second wafer substrate. Step 716 is forming front side reflective and anti-reflective coatings over the silicon layer, such that one of the reflective and anti-reflective coatings are opposite the backside compensating reflectivity coating to compensate for bending due to temperature changes and differences in coefficients of thermal expansion. Finally, step 718 is etching the anti-reflective coating and silicon layer to form a micro structure.

In summary, embodiments provide a micro-electromechanical system (MEMS) structure with a cavity region 526 on a first wafer substrate 524. A suspended silicon layer 304 is over the cavity region. A front side reflective coating 401 is over the suspended silicon layer. A front side anti-reflective coating (402, 406, 502, 504, 506) is over the suspended silicon layer. A backside compensating reflectivity coating (510, 512, 514, 518, 520) is on a bottom surface of the suspended silicon layer, inside the cavity, positioned opposite of either the front side reflective coating or the front side anti-reflective coating. The backside compensating reflectivity coating compensates for bending due to temperature changes and differences in coefficients of thermal expansion.

### Example LiDAR System Implementing Aspects of Embodiments Herein

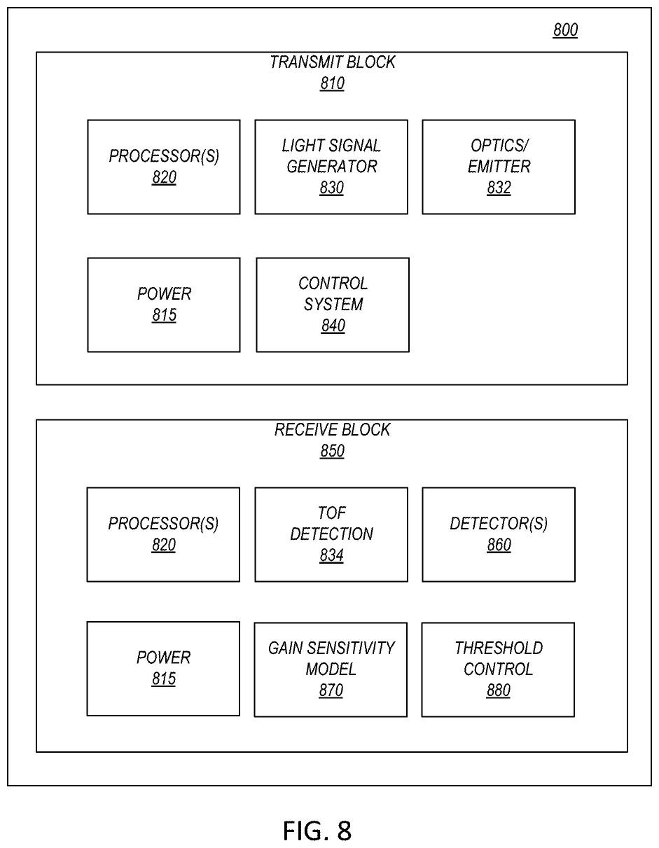

FIG. 8 illustrates a simplified block diagram showing aspects of a LiDAR-based detection system 800 incorporating the micro mirror backside coating compensation described above, according to certain embodiments. System 800 may be configured to transmit, detect, and process LiDAR signals to perform object detection as described above with regard to LiDAR system 100 described in FIG. 1. In general, a LiDAR system 800 includes one or more transmitters (e.g., transmit block 810) and one or more receivers (e.g., receive block 850). LiDAR system 800 may further include additional systems that are not shown or described to prevent obfuscation of the novel features described herein.

Transmit block 810, as described above, can incorporate a number of systems that facilitate that generation and emission of a light signal, including dispersion patterns (e.g., 360 degree planar detection), pulse shaping and frequency control, Time-Of-Flight (TOF) measurements, and any other control systems to enable the LiDAR system to emit pulses in the manner described above. In the simplified representation of FIG. 8, transmit block 810 can include processor(s) 820, light signal generator 830, optics/emitter module 832, power block 815 and control system 840. Some of all of system blocks 820-840 can be in electrical communication with processor(s) 820.

In certain embodiments, processor(s) 820 may include one or more microprocessors (μCs) and can be configured to control the operation of system 800. Alternatively or additionally, processor 820 may include one or more microcontrollers (MCUs), digital signal processors (DSPs), or the like, with supporting hardware, firmware (e.g., memory, programmable I/Os, etc.), and/or software, as would be appreciated by one of ordinary skill in the art. Alternatively, MCUs, μCs, DSPs, ASIC, programmable logic device, and the like, may be configured in other system blocks of system 800. For example, control system block 840 may include a local processor to certain control parameters (e.g., operation of the emitter). Processor(s) 820 may control some or all aspects of transmit block 810 (e.g., optics/emitter 832, control system 840, dual sided mirror 220 position as shown in FIG. 1, position sensitive device 250, etc.), receive block 850 (e.g., processor(s) 820) or any aspects of LiDAR system 800. In some embodiments, multiple processors may enable increased performance characteristics in system 800 (e.g., speed and bandwidth), however multiple processors are not required, nor necessarily germane to the novelty of the embodiments described herein. Alternatively or additionally, certain aspects of processing can be performed by analog electronic design, as would be understood by one of ordinary skill in the art.

Light signal generator 830 may include circuitry (e.g., a laser diode) configured to generate a light signal, which can be used as the LiDAR send signal, according to certain embodiments. In some cases, light signal generator 830 may generate a laser that is used to generate a continuous or pulsed laser beam at any suitable electromagnetic wavelengths spanning the visible light spectrum and non-visible light spectrum (e.g., ultraviolet and infra-red). In some embodiments, lasers are commonly in the range of 600-1200 nm, although other wavelengths are possible, as would be appreciated by one of ordinary skill in the art.

Optics/Emitter block 832 (also referred to as transmitter 832) may include one or more arrays of mirrors (including but not limited to dual sided mirror 220 as described above in FIG. 1 and the micro mirror backside coating compensation of FIG. 5) for redirecting and/or aiming the emitted laser pulse, mechanical structures to control spinning and/or moving of the emitter system, or other system to affect the system field-of-view, as would be appreciated by one of ordinary skill in the art with the benefit of this disclosure. For instance, some systems may incorporate a beam expander (e.g., convex lens system) in the emitter block that can help reduce beam divergence and increase the beam diameter. These improved performance characteristics may mitigate background return scatter that may add noise to the return signal. In some cases, optics/emitter block 832 may include a beam splitter to divert and sample a portion of the pulsed signal. For instance, the sampled signal may be used to initiate the TOF clock. In some cases, the sample can be used as a reference to compare with backscatter signals. Some embodiments may employ micro electromechanical mirrors (MEMS) that can reorient light to a target field. Alternatively or additionally, multi-phased arrays of lasers may be used. Any suitable system may be used to emit the LiDAR send pulses, as would be appreciated by one of ordinary skill in the art.

Power block 815 can be configured to generate power for transmit block 810, receive block 850, as well as manage power distribution, charging, power efficiency, and the like. In some embodiments, power management block 815 can include a battery (not shown), and a power grid within system 800 to provide power to each subsystem (e.g., control system 840, etc.). The functions provided by power management block 815 may be subsumed by other elements within transmit block 810, or may provide power to any system in LiDAR system 800. Alternatively, some embodiments may not include a dedicated power block and power may be supplied by a number of individual sources that may be independent of one another.

Control system 840 may control aspects of light signal generation (e.g., pulse shaping), optics/emitter control, TOF timing, or any other function described herein. In some cases, aspects of control system 840 may be subsumed by processor(s) 820, light signal generator 830, or any block within transmit block 810, or LiDAR system 800 in general.

Receive block 850 may include circuitry configured to detect and process a return light pulse to determine a distance of an object, and in some cases determine the dimensions of the object, the velocity and/or acceleration of the object, and the like. Processor(s) 1065 may be configured to perform operations such as processing received return pulses from detectors(s) 860, controlling the operation of TOF module 834, controlling threshold control module 880, or any other aspect of the functions of receive block 850 or LiDAR system 800 in general.

TOF module 834 may include a counter for measuring the time-of-flight of a round trip for a send and return signal. In some cases, TOF module 834 may be subsumed by other modules in LiDAR system 800, such as control system 840, optics/emitter 832, or other entity. TOF modules 834 may implement return “windows” that limit a time that LiDAR system 800 looks for a particular pulse to be returned. For example, a return window may be limited to a maximum amount of time it would take a pulse to return from a maximum range location (e.g., 250 m). Some embodiments may incorporate a buffer time (e.g., maximum time plus 10%). TOF module 834 may operate independently or may be controlled by other system block, such as processor(s) 820, as described above. In some embodiments, transmit block may also include a TOF detection module. One of ordinary skill in the art with the benefit of this disclosure would appreciate the many modification, variations, and alternative ways of implementing the TOF detection block in system 800.

Detector(s) 860 may detect incoming return signals that have reflected off of one or more objects. In some cases, LiDAR system 800 may employ spectral filtering based on wavelength, polarization, and/or range to help reduce interference, filter unwanted frequencies, or other deleterious signals that may be detected. Typically, detector(s) 860 can detect an intensity of light and records data about the return signal (e.g., via coherent detection, photon counting, analog signal detection, or the like). Detector (s) 860 can use any suitable photodetector technology including solid state photodetectors (e.g., silicon avalanche photodiodes, complimentary metal-oxide semiconductors (CMOS), charge-coupled devices (CCD), hybrid CMOS/CCD devices) or photomultipliers. In some cases, a single receiver may be used or multiple receivers may be configured to operate in parallel.

Gain sensitivity model 870 may include systems and/or algorithms for determining a gain sensitivity profile that can be adapted to a particular object detection threshold. The gain sensitivity profile can be modified based on a distance (range value) of a detected object (e.g., based on TOF measurements). In some cases, the gain profile may cause an object detection threshold to change at a rate that is inversely proportional with respect to a magnitude of the object range value. A gain sensitivity profile may be generated by hardware/software/firmware, or gain sensor model 870 may employ one or more look up tables (e.g., stored in a local or remote database) that can associate a gain value with a particular detected distance or associate an appropriate mathematical relationship there between (e.g., apply a particular gain at a detected object distance that is 10% of a maximum range of the LiDAR system, apply a different gain at 15% of the maximum range, etc.). In some cases, a Lambertian model may be used to apply a gain sensitivity profile to an object detection threshold. The Lambertian model typically represents perfectly diffuse (matte) surfaces by a constant bidirectional reflectance distribution function (BRDF), which provides reliable results in LiDAR system as described herein. However, any suitable gain sensitivity profile can be used including, but not limited to, Oren-Nayar model, Nanrahan-Krueger, Cook-Torrence, Diffuse BRDF, Limmel-Seeliger, Blinn-Phong, Ward model, HTSG model, Fitted Lafortune Model, or the like. One of ordinary skill in the art with the benefit of this disclosure would understand the many alternatives, modifications, and applications thereof.

Threshold control block 880 may set an object detection threshold for LiDAR system 800. For example, threshold control block 880 may set an object detection threshold over a certain a full range of detection for LiDAR system 800. The object detection threshold may be determined based on a number of factors including, but not limited to, noise data (e.g., detected by one or more microphones) corresponding to an ambient noise level, and false positive data (typically a constant value) corresponding to a rate of false positive object detection occurrences for the LiDAR system. In some embodiments, the object detection threshold may be applied to the maximum range (furthest detectable distance) with the object detection threshold for distances ranging from the minimum detection range up to the maximum range being modified by a gain sensitivity model (e.g., Lambertian model).

Although certain systems may not expressly discussed, they should be considered as part of system 800, as would be understood by one of ordinary skill in the art. For example, system 800 may include a bus system (e.g., CAMBUS) to transfer power and/or data to and from the different systems therein. In some embodiments, system 800 may include a storage subsystem (not shown). A storage subsystem can store one or more software programs to be executed by processors (e.g., in processor(s) 820). It should be understood that “software” can refer to sequences of instructions that, when executed by processing unit(s) (e.g., processors, processing devices, etc.), cause system 800 to perform certain operations of software programs.

The instructions can be stored as firmware residing in read only memory (ROM) and/or applications stored in media storage that can be read into memory for processing by processing devices. Software can be implemented as a single program or a collection of separate programs and can be stored in non-volatile storage and copied in whole or in-part to volatile working memory during program execution. From a storage subsystem, processing devices can retrieve program instructions to execute in order to execute various operations (e.g., software-controlled spring auto-adjustment, etc.) as described herein. Some software controlled aspects of LiDAR system 800 may include aspects of gain sensitivity model 870, threshold control 880, control system 840, TOF module 834, or any other aspect of LiDAR system 800.

It should be appreciated that system 800 is meant to be illustrative and that many variations and modifications are possible, as would be appreciated by one of ordinary skill in the art. System 800 can include other functions or capabilities that are not specifically described here. For example, LiDAR system 800 may include a communications block (not shown) configured to enable communication between LiDAR system 800 and other systems of the vehicle or remote resource (e.g., remote servers), etc., according to certain embodiments. In such cases, the communications block can be configured to provide wireless connectivity in any suitable communication protocol (e.g., radio-frequency (RF), Bluetooth, BLE, infra-red (IR), ZigBee, Z-Wave, Wi-Fi, or a combination thereof).

While system 800 is described with reference to particular blocks (e.g., threshold control block 880), it is to be understood that these blocks are defined for understanding certain embodiments of the invention and is not intended to imply that embodiments are limited to a particular physical arrangement of component parts. The individual blocks need not correspond to physically distinct components. Blocks can be configured to perform various operations, e.g., by programming a processor or providing appropriate processes, and various blocks may or may not be reconfigurable depending on how the initial configuration is obtained. Certain embodiments can be realized in a variety of apparatuses including electronic devices implemented using any combination of circuitry and software. Furthermore, aspects and/or portions of system 800 may be combined with or operated by other sub-systems as informed by design. For example, power management block 815 and/or threshold control block 880 may be integrated with processor(s) 820 instead of functioning as separate entities.

### Example Computer Systems Implementing Aspects of Embodiments Herein

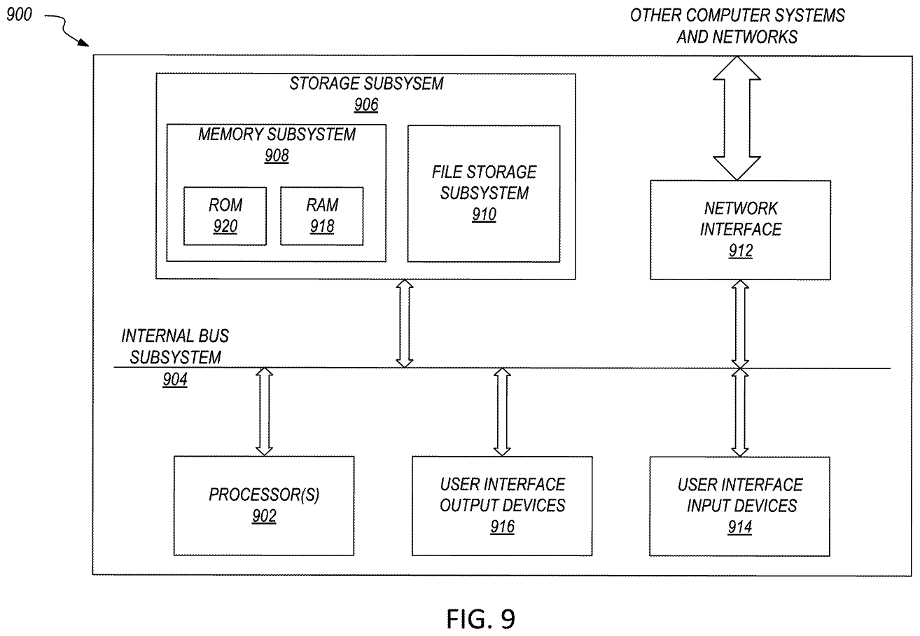

FIG. 9 is a simplified block diagram of computer system 900 configured to operate aspects of a LiDAR-based detection system, according to certain embodiments. Computer system 900 can be used to implement any of the systems and modules discussed above with respect to FIGS. 1-2B. For example, computer system 900 may operate aspects of threshold control 880, TOF module 834, processor(s) 820, control system 840, or any other element of LiDAR system 800 or other system described herein. Computer system 900 can include one or more processors 902 that can communicate with a number of peripheral devices (e.g., input devices) via a bus subsystem 904. These peripheral devices can include storage subsystem 906 (comprising memory subsystem 908 and file storage subsystem 910), user interface input devices 914, user interface output devices 916, and a network interface subsystem 912.

In some examples, internal bus subsystem 904 (e.g., CAMBUS) can provide a mechanism for letting the various components and subsystems of computer system 900 communicate with each other as intended. Although internal bus subsystem 904 is shown schematically as a single bus, alternative embodiments of the bus subsystem can utilize multiple buses. Additionally, network interface subsystem 912 can serve as an interface for communicating data between computer system 900 and other computer systems or networks. Embodiments of network interface subsystem 912 can include wired interfaces (e.g., Ethernet, CAN, RS232, RS485, etc.) or wireless interfaces (e.g., ZigBee, Wi-Fi, cellular, etc.).

In some cases, user interface input devices 914 can include a keyboard, pointing devices (e.g., mouse, trackball, touchpad, etc.), a barcode scanner, a touch-screen incorporated into a display, audio input devices (e.g., voice recognition systems, microphones, etc.), Human Machine Interfaces (HMI) and other types of input devices. In general, use of the term “input device” is intended to include all possible types of devices and mechanisms for inputting information into computer system 900. Additionally, user interface output devices 916 can include a display subsystem, a printer, or non-visual displays such as audio output devices, etc. The display subsystem can be any known type of display device. In general, use of the term “output device” is intended to include all possible types of devices and mechanisms for outputting information from computer system 900.

Storage subsystem 906 can include memory subsystem 908 and file/disk storage subsystem 910. Subsystems 908 and 910 represent non-transitory computer-readable storage media that can store program code and/or data that provide the functionality of embodiments of the present disclosure. In some embodiments, memory subsystem 908 can include a number of memories including main random access memory (RAM) 918 for storage of instructions and data during program execution and read-only memory (ROM) 920 in which fixed instructions may be stored. File storage subsystem 910 can provide persistent (i.e., non-volatile) storage for program and data files, and can include a magnetic or solid-state hard disk drive, an optical drive along with associated removable media (e.g., CD-ROM, DVD, Blu-Ray, etc.), a removable flash memory-based drive or card, and/or other types of storage media known in the art. The memory system can contain a look-up table providing the wavelength corresponding to a detected temperature of the laser diode.

It should be appreciated that computer system 900 is illustrative and not intended to limit embodiments of the present disclosure. Many other configurations having more or fewer components than system 900 are possible.

The various embodiments further can be implemented in a wide variety of operating environments, which in some cases can include one or more user computers, computing devices or processing devices, which can be used to operate any of a number of applications. User or client devices can include any of a number of general purpose personal computers, such as desktop or laptop computers running a standard operating system, as well as cellular, wireless and handheld devices running mobile software and capable of supporting a number of networking and messaging protocols. Such a system also can include a number of workstations running any of a variety of commercially available operating systems and other known applications for purposes such as development and database management. These devices also can include other electronic devices, such as dummy terminals, thin-clients, gaming systems and other devices capable of communicating via a network.

Most embodiments utilize at least one network that would be familiar to those skilled in the art for supporting communications using any of a variety of commercially available protocols, such as TCP/IP, UDP, OSI, FTP, UPnP, NFS, CIFS, and the like. The network can be, for example, a local-area network, a wide-area network, a virtual private network, the Internet, an intranet, an extranet, a public switched telephone network, an infrared network, a wireless network, and any combination thereof.

In embodiments utilizing a network server, the network server can run any of a variety of server or mid-tier applications, including HTTP servers, FTP servers, CGI servers, data servers, Java servers, and business application servers. The server(s) also may be capable of executing programs or scripts in response to requests from user devices, such as by executing one or more applications that may be implemented as one or more scripts or programs written in any programming language, including but not limited to Java®, C, C# or C++, or any scripting language, such as Perl, Python or TCL, as well as combinations thereof. The server(s) may also include database servers, including without limitation those commercially available from Oracle®, Microsoft®, Sybase®, and IBM®.

The environment can include a variety of data stores and other memory and storage media as discussed above. These can reside in a variety of locations, such as on a storage medium local to (and/or resident in) one or more of the computers or remote from any or all of the computers across the network. In a particular set of embodiments, the information may reside in a storage-area network (SAN) familiar to those skilled in the art. Similarly, any necessary files for performing the functions attributed to the computers, servers or other network devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch screen or keypad), and at least one output device (e.g., a display device, printer or speaker). Such a system may also include one or more storage devices, such as disk drives, optical storage devices, and solid-state storage devices such as RAM or ROM, as well as removable media devices, memory cards, flash cards, etc.

Such devices also can include a computer-readable storage media reader, a communications device (e.g., a modem, a network card (wireless or wired), an infrared communication device, etc.), and working memory as described above. The computer-readable storage media reader can be connected with, or configured to receive, a non-transitory computer readable storage medium, representing remote, local, fixed, and/or removable storage devices as well as storage media for temporarily and/or more permanently containing, storing, transmitting, and retrieving computer-readable information. The system and various devices also typically will include a number of software applications, modules, services or other elements located within at least one working memory device, including an operating system and application programs, such as a client application or browser. It should be appreciated that alternate embodiments may have numerous variations from that described above. For example, customized hardware might also be used and/or particular elements might be implemented in hardware, software (including portable software, such as applets) or both. Further, connection to other computing devices such as network input/output devices may be employed.

Non-transitory storage media and computer-readable storage media for containing code, or portions of code, can include any appropriate media known or used in the art such as, but not limited to, volatile and non-volatile, removable and non-removable media implemented in any method or technology for storage of information such as computer-readable instructions, data structures, program modules or other data, including RAM, ROM, Electrically Erasable Programmable Read-Only Memory (EEPROM), flash memory or other memory technology, CD-ROM, DVD or other optical storage, magnetic cassettes, magnetic tape, magnetic disk storage or other magnetic storage devices or any other medium which can be used to store the desired information and which can be accessed by a system device. Based on the disclosure and teachings provided herein, a person of ordinary skill in the art will appreciate other ways and/or methods to implement the various embodiments. However, computer-readable storage media does not include transitory media such as carrier waves or the like.

Other variations are within the spirit of the present disclosure. Thus, while the disclosed techniques are susceptible to various modifications and alternative constructions, certain illustrated examples thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims. For instance, any of the examples, alternative examples, etc., and the concepts thereof may be applied to any other examples described and/or within the spirit and scope of the disclosure.

For example, instead of using a single laser to illuminate the array of MEMS mirrors, an array of lasers may be used. Also, the pattern generation and decoding could be hard-wired, in firmware or in software in different embodiments.

The micro mirror backside coating compensation structure of the present invention can be used in a variety of other applications than LIDAR. For example, light beam steering techniques can also be used in other optical systems, such as optical display systems (e.g., TVs), optical sensing systems, optical imaging systems, and the like. In various light beam steering systems, the light beam may be steered by, for example, a rotating platform driven by a motor, a multi-dimensional mechanical stage, a Galvo-controlled mirror, a resonant fiber, an array of microelectromechanical (MEMS) mirrors, or any combination thereof. A MEMS micro-mirror may be rotated around a pivot or connection point by, for example, a micro-motor, an electromagnetic actuator, an electrostatic actuator, or a piezoelectric actuator.

The MEMS mirror structure of the present invention can have the mirror mass driven by different types of actuators. In some light steering systems, the transmitted or received light beam may be steered by an array of micro-mirrors. Each micro-mirror may rotate around a pivot or connection point to deflect light incident on the micro-mirror to desired directions. The performance of the micro-mirrors may directly affect the performance of the light steering system, such as the field of view (FOV), the quality of the point cloud, and the quality of the image generated using a light steering system. For example, to increase the detection range and the FOV of a LiDAR system, micro-mirrors with large rotation angles and large apertures may be used, which may cause an increase in the maximum displacement and the moment of inertia of the micro-mirrors. To achieve a high resolution, a device with a high resonant frequency may be used, which may be achieved using a rotating structure with a high stiffness. It may be difficult to achieve this desired performance using electrostatic actuated micro-mirrors because comb fingers used in an electrostatic-actuated micro-mirror may not be able to provide the force and moment needed and may disengage at large rotation angles, in particular, when the aperture of the micro-mirror is increased to improve the detection range. Some piezoelectric actuators may be used to achieve large displacements and large scanning angles due to their ability to provide a substantially larger drive force than electrostatic-actuated types, with a relatively lower voltage.

The use of the terms “a” and “an” and “the” and similar referents in the context of describing the disclosed examples (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate examples of the disclosure and does not pose a limitation on the scope of the disclosure unless otherwise claimed. No language in the specification should be construed as indicating any non-claimed element as essential to the practice of the disclosure.

What is claimed is:

1. A method for forming a compensating reflectivity layer on an underside of suspended structures in an optical micro-electromechanical system (MEMS) mirror system for reflecting a laser beam in a light detection and ranging (LiDAR) system, comprising:
etching a connector region on a first wafer substrate using Deep Reactive Iron Etch (DRIE) to form a first trench;
etching a mirror cavity region on the first wafer substrate using DRIE to form a second trench shallower than the first trench;
forming a first oxide layer and a silicon layer over a second wafer substrate;
depositing a compensating reflectivity coating on the silicon layer;
etching away the compensating reflectivity coating with a pattern to leave a backside compensating reflectivity coating;
flipping the second wafer substrate over, and aligning first areas without the compensating reflectivity coating with second areas without trenches on the first wafer substrate;
bonding the first and second areas to each other;
removing the second wafer substrate and first oxide layer;
forming front side reflective and anti-reflective layers over the silicon layer; and
etching the anti-reflective coating and silicon layer to form a micro mirror structure.

2. The method of claim 1 wherein the reflectivity layer is an anti-reflective layer.

3. The method of claim 1 wherein the reflectivity layer is a reflective layer.

4. The method of claim 1, wherein the etching the anti-reflective layer and silicon layer to form a micro mirror structure leaves a plurality of comb fingers with anti-reflective coatings on both top and bottom sides.

5. The method of claim 1, wherein the bonding is performed with a high temperature anneal.

6. The method of claim 1, further comprising, before the bonding of the first wafer substrate and the silicon layer at the first and second areas, aligning protrusions at edges of the mirror cavity region with recesses formed at the first and second areas between the anti-reflective coating.

7. The method of claim 1, wherein removing the second wafer substrate and first oxide layer further comprises:
mechanically grinding the second wafer substrate to leave coarse remains of the second wafer substrate; and
etching to remove coarse remains of the second wafer substrate and the first oxide layer.

8. The method of claim 1, further comprising:
depositing a metal reflective layer over the first silicon layer.

9. A method for forming a compensating reflectivity layer on an underside of suspended structures, comprising:
forming a cavity region on a first wafer substrate;
forming a silicon layer over a second wafer substrate;
depositing a compensating reflectivity coating on the silicon layer;
etching away the compensating reflectivity coating with a pattern to leave a backside compensating reflectivity coating;
flipping the second wafer substrate over, and aligning first areas without the compensating reflectivity coating with second areas without the cavity region on the first wafer substrate;
bonding the first and second areas to each other;
removing the second wafer substrate;
forming front side reflective and anti-reflective coatings over the silicon layer, such that one of the reflective and anti-reflective coatings are opposite the backside compensating reflectivity coating to compensate for bending due to temperature changes and differences in coefficients of thermal expansion; and
etching the anti-reflective coating and silicon layer to form a micro structure.

10. The method of claim 9 wherein the compensating reflectivity coating is an anti-reflective layer.

11. The method of claim 9 wherein the compensating reflectivity coating is a reflective layer.

12. The method of claim 9, further comprising:
forming an oxide layer between the silicon layer and the second wafer substrate; and
removing the oxide layer after removing the second wafer substrate.

13. The method of claim 12, wherein the cavity is a mirror cavity and the micro structure is a micro-electromechanical system (MEMS) micro mirror structure.

14. The method of claim 13 wherein the reflectivity layer is a dielectric anti-reflective layer.

15. The method of claim 14 further comprising:
forming anchors and comb fingers as part of the MEMS micro mirror structure; and
wherein the dielectric anti-reflective layer is formed on the backside of the comb fingers and suspended portions of the anchors.

16. The method of claim 9, wherein the bonding is performed with a high temperature anneal.

17. The method of claim 9, wherein the step of aligning first areas without the compensating reflectivity coating with second areas without the cavity region on the first wafer substrate further comprises:
aligning protrusions at edges of the cavity region with recesses formed at the first and second areas between the compensating reflectivity coating.

18. A micro-electromechanical system (MEMS) structure comprising:
a cavity region on a first wafer substrate;
a suspended silicon layer over the cavity region;
a front side reflective coating over the suspended silicon layer;
a front side anti-reflective coating over the suspended silicon layer;
a backside compensating reflectivity coating on a bottom surface of the suspended silicon layer, inside the cavity, positioned opposite either the front side reflective coating or the front side anti-reflective coating; and
wherein the backside compensating reflectivity coating compensates for bending due to temperature changes and differences in coefficients of thermal expansion.

19. The MEMS structure of claim 18, wherein the compensating reflectivity coating is an anti-reflective layer.

20. The MEMS structure of claim 18 wherein the MEMS structure is a micro mirror structure.
